(19) United States
(12) Patent Application Publication
(10) Pub. No.: US 2015/0147838 A1
(43) Pub. Date: May 28, 2015

(54) MANUFACTURING METHOD OF DISPLAY DEVICE

(71) Applicant: Japan Display Inc., Tokyo (JP)

(72) Inventor: Takeshi OOKAWARA, Tokyo (JP)

(21) Appl. No.: 14/552,876

(22) Filed: Nov. 25, 2014

(30) Foreign Application Priority Data
Nov. 26, 2013 (JP) 2013-243788

(51) Int. Cl. H01L 51/56

(52) U.S. Cl. CPC H01L 51/56
USPC 438/34

(57) ABSTRACT

A manufacturing method of a display device of the invention includes a step of forming an organic layer in correspondence with respective pixels on a substrate having a display area and a non-display area, the step of forming the organic layer includes a step of depositing a material of the organic layer using a mask having a frame-like frame and a mask foil fixed to the frame, the mask foil has openings provided in an area corresponding to the display area and dummy holes provided along an outer periphery of the area corresponding to the display area in an area corresponding to the non-display area, and an area of a plan view shape of the dummy hole adjacent to a midpoint of a side of the outer periphery is larger than an area of a plan view shape of the dummy hole adjacent to a corner of the outer periphery.

### CROSS-REFERENCE TO RELATED APPLICATION

The present application claims priority from Japanese application JP 2013-243788 filed on Nov. 26, 2013, the content of which is hereby incorporated by reference into this application.

### BACKGROUND OF THE INVENTION

1. Field of the Invention

This invention relates to a manufacturing method of a display device.

2. Description of the Prior Art

As thinner and lighter light emitting sources, organic electro luminescent elements have received attention and display devices including many organic electro luminescent elements have been developed. The organic electro luminescent element has a structure in which an organic layer having a light emitting layer is sandwiched between a lower electrode and an upper electrode.

As a manufacturing method of the display device, in JP 2005-148335 A, a method of evaporating an organic layer on a substrate having a display area and a non-display area using an evaporation mask of a metal foil tensed and fixed to a frame having a picture frame shape is disclosed. In an area of the evaporation mask corresponding to the display area described in JP 2005-148335 A, an opening pattern (mask pattern) corresponding to respective pixels is provided. Further, in an area of the evaporation mask corresponding to the non-display area, an opening pattern larger than the mask pattern is provided.

### SUMMARY OF THE INVENTION

According to the manufacturing method of the display device described in JP 2005-148335 A, on the metal foil of the evaporation mask, the stronger tension from the frame acts in the part farther away from the corner of the frame. Accordingly, the opening pattern in the area corresponding to the non-display area and the mask pattern around the opening pattern are deformable. That may cause reduction in accuracy of the positions in which the organic layer is evaporated in the display area.

The invention has been achieved in view of the above described situations, and an object of the invention is to realize a manufacturing method of a display device that can suppress deterioration in quality of the display device.

The summary of representatives of the inventions disclosed in this application will be briefly explained as below.

(1) A manufacturing method of a display device of the invention includes a step of forming an organic layer having a light emitting layer in correspondence with respective pixels on a substrate having a display area having a rectangular plan view shape and a non-display area surrounding an outer periphery of the display area, the step of forming the organic layer includes a step of depositing a material of the organic layer using a mask having a frame-like frame and a mask foil fixed to the frame, the mask foil has openings respectively corresponding to the pixels provided in an area corresponding to the display area and a plurality of dummy holes provided along an outer periphery of the area corresponding to the display area in an area corresponding to the non-display area, and an area of a plan view shape of the dummy hole adjacent to a midpoint of a side of the outer periphery is larger than an area of a plan view shape of the dummy hole adjacent to a corner of the outer periphery.

(2) In the manufacturing method of the display device of the invention, in (1), the plan view shape of the frame may be a rectangular shape, and an area of a plan view shape of the dummy hole adjacent to a midpoint of a side of the frame may be larger than an area of a plan view shape of the dummy hole adjacent to a corner of the frame.

(3) In the manufacturing method of the display device of the invention, in (1) or (2), the area of the plan view shape of the dummy hole maybe larger as the dummy hole is farther from the corner of the outer periphery of the area corresponding to the display area.

(4) In the manufacturing method of the display device of the invention, in any one of (1) to (3), the plan view shape of the dummy hole may be a circular shape.

(5) In the manufacturing method of the display device of the invention, in any one of (1) to (4), the dummy hole may penetrate the mask foil.

(6) In the manufacturing method of the display device of the invention, in any one of (1) to (4), a thickness of the mask foil in the dummy hole may be smaller than a thickness of the mask foil outside of the dummy hole.

### BRIEF DESCRIPTION OF THE DRAWINGS

FIG. 1 is a schematic perspective view of a mother substrate showing a manufacturing method of a display device according to one embodiment of the invention.

FIG. 2 is a schematic sectional view of the mother substrate along II-II section line shown in FIG. 1 for explanation of the manufacturing method of the display device according to the one embodiment of the invention.

FIG. 3 is a schematic perspective view showing a state in which a mask is placed on the mother substrate shown in FIG. 1 in the same visual field as that in FIG. 1.

FIG. 4 is a partially enlarged view of IV areas of the mask shown in FIG. 3.

FIG. 5 is a schematic sectional view in the same visual field as that in FIG. 2 for explanation of the manufacturing method of the display device according to the one embodiment of the invention.

FIG. 6 is a schematic sectional view showing deposition performed in the state in which the mask is placed on the mother substrate.

FIG. 7 is a schematic plan view showing the display device manufactured according to the embodiment.

FIG. 8 is a schematic plan view showing a modified example of the mask in the same visual field as that in FIG. 4.

FIG. 9 is a schematic plan view showing a modified example of the mask in the same visual field as that in FIG. 4.

### DETAILED DESCRIPTION OF THE INVENTION

As below, as an example of a manufacturing method of a display device according to one embodiment of the invention, a manufacturing method of an organic electro luminescent display device will be explained with reference to the drawings. Note that the drawings for reference in the following explanation may enlarge and show characteristic parts for convenience for making the characteristics understandable, and the dimension ratios etc. of the respective component elements are not necessarily the same as the actual dimension ratios. Further, the materials etc. exemplified in the following explanation are just examples, and the respective component elements may be different from those and may be changed and implemented in a range in which the scope of the invention is unchanged.

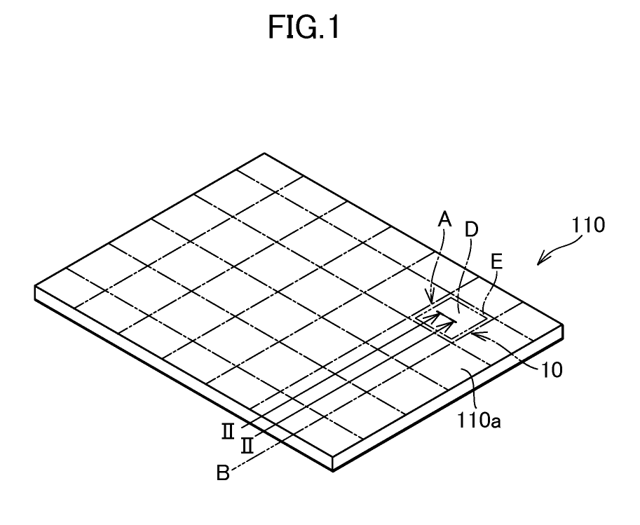

First, a mother substrate 110 is prepared. FIG. 1 is a schematic perspective view of the mother substrate 110 showing a manufacturing method of a display device (organic electro luminescent display device) according to one embodiment of the invention. The mother substrate 110 is an insulating substrate. On an upper surface 110a of the mother substrate 110, a circuit layer and organic electro luminescent elements, which will be described later, are formed.

On the mother substrate 110, organic electro luminescent display device formation areas A are arranged in a matrix form. The mother substrate 110 is cut along boundaries B between the organic electro luminescent display device formation areas A, and thereby, substrates 10 of the organic electro luminescent display devices, which will be described later, are formed.

In each of the organic electro luminescent display device formation areas A, a display area D having a rectangular plan view shape and a non-display area E surrounding each display area D in the plan view are provided. In the display area D, pixels P, which will be described later, are arranged in a matrix form.

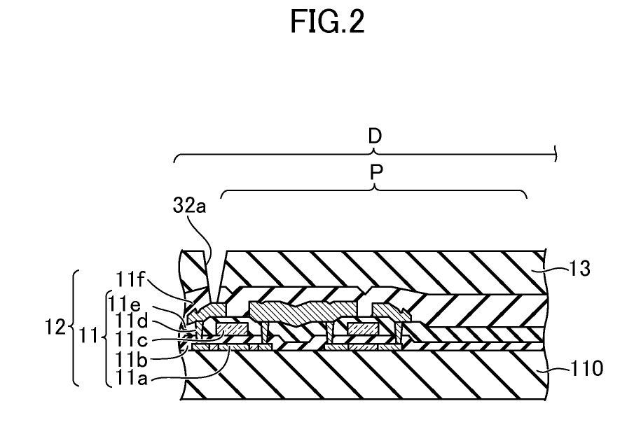

Then, on each of the organic electro luminescent display device formation areas A of the mother substrate 110, a circuit layer 12 having thin-film transistors 11 is formed. FIG. 2 is a schematic sectional view of the mother substrate 110 along II-II section line shown in FIG. 1 for explanation of the manufacturing method of the display device (organic electro luminescent display device) according to the one embodiment of the invention.

First, on each of the display areas D of the mother substrate 110, a polysilicon semiconductor layer 11a, agate insulating layer 11b, a layer of a gate electrode 11c, a layer of a source-drain electrode 11d, and an interlayer insulating film 11e are sequentially stacked and patterned. Thereby, the thin-film transistors 11 are formed with respect to each pixel P in each of the display areas D of the mother substrate 110.

Then, a passivation film 11f as an insulating film that protects the thin-film transistors 11 is formed to cover the thin-film transistors 11. In this manner, the circuit layer 12 having the thin-film transistors 11 and the passivation film 11f is formed.

Then, a planarizing film 13 of a material having insulation properties e.g., SiO₂, SiN, acrylic, or polyimide is formed to cover the circuit layer 12. The planarizing film 13 is formed on the circuit layer 12, and thereby, electrical insulation between the adjacent thin-film transistors 11 and between the thin-film transistors 11 and organic electro luminescent elements 30, which will be described later, is obtained.

Then, contact holes 32a penetrating the planarizing film 13 and the passivation film 11f and exposing part of the upper surface of the source-drain electrode 11d are formed with respect to each pixel P.

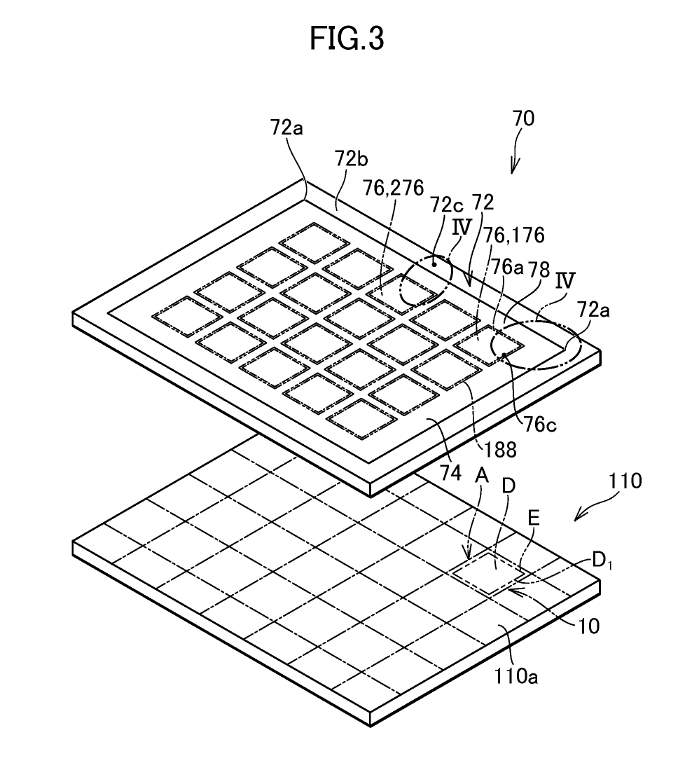

Then, the organic electro luminescent elements are formed on the planarizing film 13. FIG. 3 is a schematic perspective view showing a state in which a mask 70 is placed on the mother substrate 110 shown in FIG. 1 in the same visual field as that in FIG. 1.

First, the configuration of the mask 70 is explained. The mask 70 is a mask for deposition for formation of the organic electro luminescent elements. The mask 70 has a frame 72 having a rectangular plan view shape and a mask foil 74 fixed to the frame 72. The frame 72 is a member for fixing the mask foil 74, e.g., a frame-like metal. The mask foil 74 is a member for deposition of an organic layer, which will be described later, with respect to each pixel P on the mother substrate 110, e.g., a metal foil. The mask foil 74 is tensed and fixed to the frame 72.

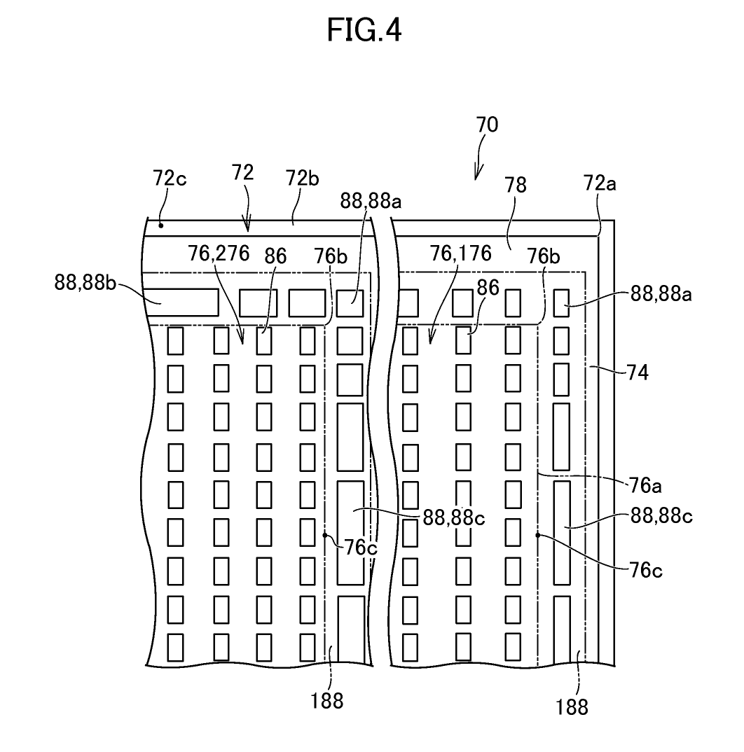

As shown in FIG. 3, the mask foil 74 has areas for display area 76 and areas for non-display area 78. The areas for display area 76 are areas corresponding to the display areas D of the mother substrate 110 and have rectangular plan view shapes. The areas for non-display area 78 are areas corresponding to the non-display areas E of the mother substrate 110. Further, dummy hole formation areas 188 as areas in which dummy holes, which will be described later, are provided to surround the outer peripheries of the respective areas for display area 76. As below, the details of the configuration of the mask foil 74 will be explained using FIGS. 3 and 4.

FIG. 4 is a partially enlarged view of IV areas of the mask 70 shown in FIG. 3. In FIG. 4, for convenience of explanation, both areas of the areas for display area 76 (176) adjacent to a corner 72a of the frame 72 and the areas for display area 76 (276) adjacent to a midpoint 72c of a side 72b of the frame 72 are shown. In FIG. 4, for convenience of explanation, the dimension ratios of the frame 72 and the areas for display area 76 and the number of dummy holes 88 are different from those of the actual configuration.

In the areas for display area 76 of the mask foil 74, openings 86 corresponding to the respective pixels P are provided. Further, in the dummy hole formation areas 188 of the areas for non-display area 78, a plurality of dummy holes 88 provided along the outer peripheries 76a of the areas for display area 76 are provided. Note that, as shown in FIG. 3, the outer peripheries 76a of the areas for display area 76 correspond to the outer peripheries of the display areas D of the mother substrate 110.

As shown in FIG. 4, the sizes of the plan view shapes of the dummy holes 88 in the mask foil 74 in the embodiment are not uniform. In the areas for non-display area 78 having the frame-like plan view shapes, the portion of the dummy holes 88 is larger in an area within a fixed range from the midpoint 72c than in an area within a fixed range from the corner 72a.

Specifically, as shown in FIG. 4, the area of the plan view shape of the dummy hole 88b adjacent to the midpoint 72c of the side 72b of the frame 72 is larger than the area of the plan view shape of the dummy hole 88a adjacent to the corner 72a of the frame 72. Further, as shown in FIG. 4, the area of the plan view shape of the dummy hole 88a adjacent to a corner 76b of the area for display area 276 may be larger than the area of the plan view shape of the dummy hole 88a adjacent to a corner 76b of the area for display area 176.

Note that “the dummy hole 88a adjacent to the corner 72a” in the embodiment refers to the dummy hole 88 closest to the corner 72a of the plurality of dummy holes 88 provided in the mask foil 74. Similarly, “the dummy hole 88b adjacent to the midpoint 72c of the side 72b” in the embodiment refers to the dummy hole 88 closest to the midpoint of the side of the frame 72 (the point at equal distances from adjacent two corners 72a).

Further, as shown in FIG. 4, the sizes of the dummy holes 88a adjacent to the outer peripheries 76a of the areas for display area 76 may not be uniform with respect to each area for display area 76. Specifically, it is preferable that the area of the plan view shape of the dummy hole 88c adjacent to a midpoint 76c of a side of the outer periphery 76a of the plan view shape of the area for display area 76 is larger than the area of the plan view shape of the dummy hole 88a adjacent to the corner 76b of the outer periphery of each area for display area 76.

Note that “the dummy hole 88a adjacent to the corner 76b” refers to the dummy hole 88 closest to the corner 76b of the plan view shape of the area for display area 76. Similarly, “the dummy hole 88a adjacent to the midpoint 76c of the side of the outer periphery 76a” refers to the dummy hole 88 closest to the midpoint of the side of the plan view shape of the area for display area 76 (the point at equal distances from adjacent two corners 76b).

Further, it is preferable that the areas of the plan view shapes of the dummy holes 88a adjacent to the outer peripheries 76a of the areas for display area 76 are larger as the dummy holes 88 are farther from the corner 76b of the outer periphery 76a of the area for display area 76.

The dummy hole 88 may be a hole penetrating the mask foil 74 or a concavity not penetrating the mask foil 74. Specifically, the concavity refers to a shape in which the thickness of the mask foil 74 within the dummy hole 88 is smaller than the thickness of the mask foil 74 in an area 78a outside of the dummy hole 88 (an area without the dummy hole 88 of the areas for non-display area 78). Specifically, the concave dummy hole 88 is formed by half-etching processing.

Note that, as shown in FIG. 4, the dummy holes 88 adjacent to the areas for display area 176 are formed at equal intervals, however, the intervals between the adjacent dummy holes 88 may be appropriately adjusted in response to the tension applied to the areas for display area 76. Specifically, for example, the intervals between the dummy holes 88 adjacent to the areas for display area 276 may be formed to be smaller than the intervals between the dummy holes 88 adjacent to the areas for display area 176. Further, areas where the dummy holes 88 are not formed may be provided according to the areas where application of tension is desired.

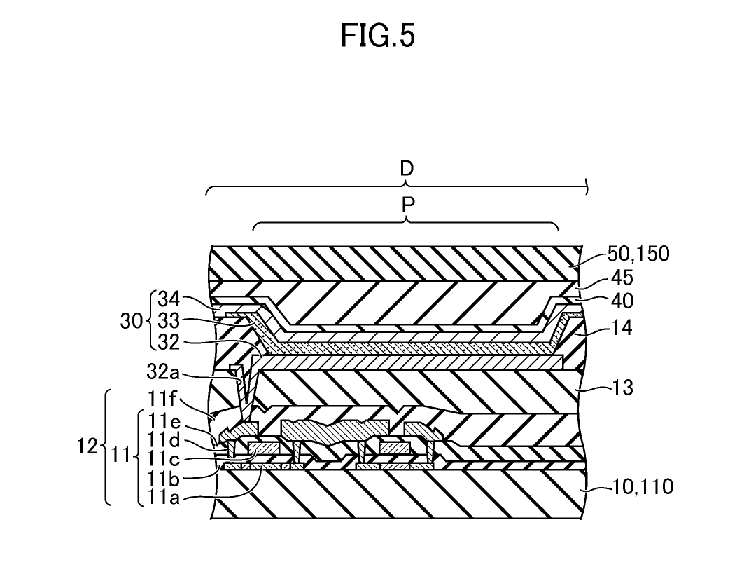

Then, lower electrodes 32, organic layers 33, and upper electrodes 34 are sequentially deposited in the areas corresponding to the respective pixels P of the mother substrate 110, and thereby, the organic electro luminescent elements 30 are formed. FIG. 5 is a schematic sectional view in the same visual field as that in FIG. 2 for explanation of the manufacturing method of the display device (organic electro luminescent display device) according to the one embodiment of the invention.

First, as shown in FIG. 5, the lower electrodes 32 are formed to cover the areas corresponding to the respective pixels P on the planarizing film 13. Thereby, the lower electrodes 32 are respectively electrically connected to the thin-film transistors 11 via the contact holes 32a.

As the material for the lower electrodes 32, specifically, e.g., ITO (Indium Tin Oxide) is preferably used, however, a material having translucency and conductivity such as IZO (indium zinc composite oxide), tin oxide, zinc oxide, indium oxide, or aluminum oxide composite oxide may be used.

At the step of forming the lower electrodes 32, the mask 70 may be used. Regarding the deposition method using the mask 70, for convenience of explanation, the details of the method will be explained at the formation step of the organic layer 33.

Then, in the display areas D, pixel separation films 14 of an insulating material are formed along the boundaries between the adjacent pixels P. Thereby, contact between the adjacent lower electrodes 32 and leakage current between the lower electrodes 32 and the upper electrodes 34 are suppressed.

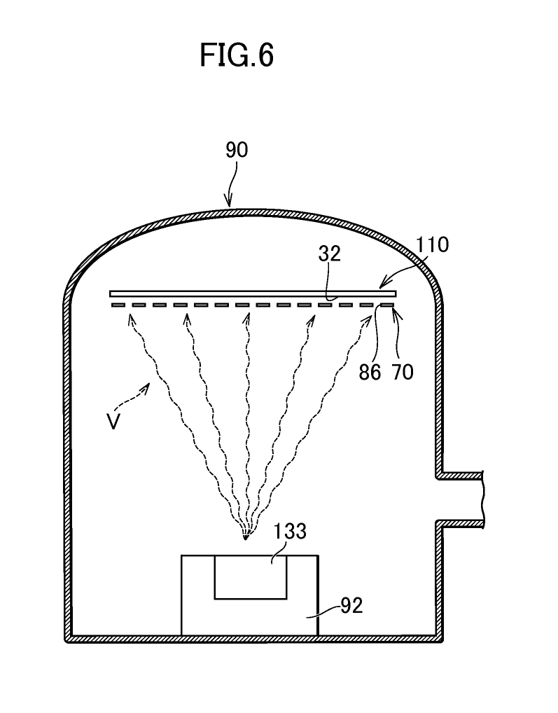

Then, the organic layers 33 are formed on the lower electrodes 32 using the mask 70. FIG. 6 is a schematic sectional view showing deposition performed in the state in which the mask 70 is placed on the mother substrate 110. First, as shown in FIG. 6, the mask 70 is placed within a chamber 90 to face the lower electrodes 32. The chamber 90 is a unit for deposition of the organic layers 33 on the mother substrate 110. Within the chamber 90, attaching means (not shown) for attaching the mother substrate 110 and a container 92 for putting an organic layer material 133 therein are placed. The mother substrate 110 and the mask 70 are attached downward to face the organic layer material 133 by the attaching means.

Then, the organic layer material 133 is sublimated within the vacuum chamber 90 using e.g., an electron gun (not shown). The sublimated organic layer material 133 turns to vapor flow V and reaches the mother substrate 110. Thereby, the organic layer material 133 is deposited in areas corresponding to the openings 86 of the mask 70.

The organic layer material 133 includes e.g., a material for hole injection layer, a material for hole transport layer, a material for light emitting layer, a material for electron transport layer, and a material for electron injection layer. They are sequentially deposited using the mask 70, and thereby, as shown in FIG. 5, the organic layers 33 having at least the light emitting layers are formed for the respective pixels P. The multilayer structure of the organic layer 33 is not limited to that described here, but may be another structure as long as it contains at least a light emitting layer.

Then, the mask 70 is removed from the mother substrate 110. Then, a conducting material having translucency such as ITO is evaporated over the organic layers 33. Thereby, the upper electrodes 34 are formed. The method of forming the upper electrodes 34 is not limited to evaporation, but another method including sputtering may be employed. In the above described manner, as shown in FIG. 5, the organic electro luminescent elements 30 are formed.

Then, sealing films 40 of e.g., silicon nitride (SiN) are formed to cover the display areas D and the non-display areas E. Then, sealing materials (not shown) are placed on the sealing film 40 to surround the respective display areas D. Then, inside of the areas surrounded by the sealing materials is filled with filling materials 45. Then, an opposed mother substrate 150 is placed to cover the upper surfaces of the sealing films 40 via the filling materials 45. The opposed mother substrate 150 is formed by e.g., a set of opposed substrates 50 of color filter substrates or the like.

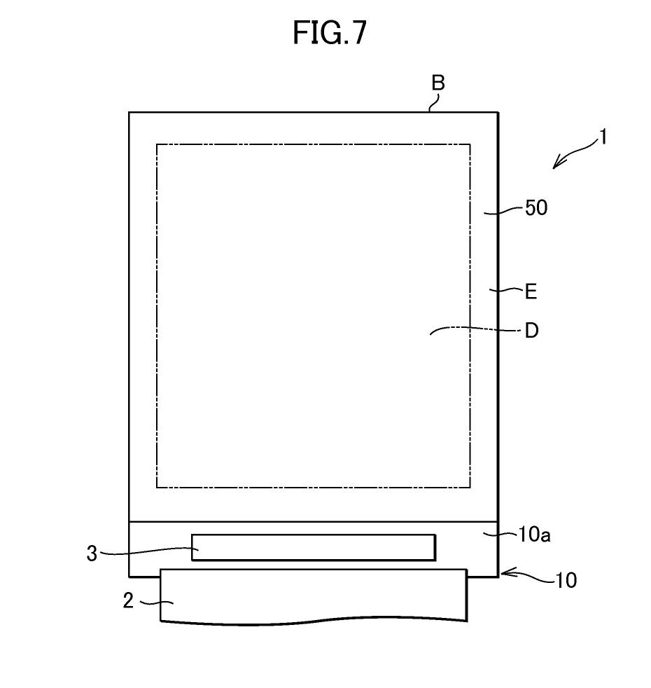

Then, as shown in FIG. 7, the opposed mother substrate 150 and the mother substrate 110 are cut along boundaries B. Thereby, the opposed mother substrate 150 and the mother substrate 110 are divided into a plurality of pieces (opposed substrates 50 and substrates 10). FIG. 7 is a schematic plan view showing the display device (organic electro luminescent display device 1) manufactured according to the embodiment.

Then, parts of the opposed substrate 50, the sealing material (not shown), and the sealing film 40 are removed, and a terminal 3 is formed on the exposed upper surface 10a of the substrate 10. Then, a flexible circuit board 2 is provided on the upper surface 10a, and thereby, the display device (organic electro luminescent display device) 1 is manufactured.

According to the manufacturing method of the display device 1 in the embodiment, the area of the plan view shape of the dummy hole 88a adjacent to the midpoint 76c of the side of the outer periphery 76a is larger than the area of the plan view shape of the dummy hole 88a adjacent to the corner 76b of the outer periphery 76a of the display area D. Thereby, according to the manufacturing method of the display device 1 in the embodiment, compared to the manufacturing method of the display device without the configuration, the tension from the frame 72 acts more easily on the dummy hole 88a adjacent to the midpoint 76c of the outer periphery 76a of the display area D having the rectangular plan view shape in each display area D.

Therefore, the action of the tension from the frame 72 on the openings 86 around the dummy hole 88a adjacent to the midpoint 76c of the outer periphery 76a of the display area D maybe suppressed. Thereby, deformation of the openings 86 in each display area D may be suppressed and reduction in accuracy of the position where the organic layer 33 is deposited in the display area D may be prevented. Accordingly, the manufacturing method that can suppress deterioration in quality of the display device 1 may be realized.

Further, according to the manufacturing method of the display device 1 in the embodiment, the area of the plan view shape of the dummy hole 88a adjacent to the midpoint 72c of the frame 72 is larger than the area of the plan view shape of the dummy hole 88a adjacent to the corner 72a of the frame 72. Thereby, according to the manufacturing method of the display device 1 in the embodiment, compared to the manufacturing method of the display device without the configuration, the tension from the frame 72 acts more easily on the dummy hole 88a adjacent to the midpoint 72c of the frame 72 than on the dummy hole 88a adjacent to the corner 72a of the frame 72.

Therefore, according to the manufacturing method of the display device 1 in the embodiment, the action of the tension from the frame 72 on the openings 86 around the dummy hole 88a adjacent to the midpoint 72c of the frame 72 may be suppressed. Thereby, deformation of the openings 86 in the display area D may be suppressed and reduction in accuracy of the position where the organic layer 33 is deposited in the display area D may be prevented, and the manufacturing method that can suppress deterioration in quality of the display device 1 may be realized.

Furthermore, according to the manufacturing method of the display device 1 in the embodiment, the area of the plan view shape of the dummy hole 88a is larger as the dummy hole 88a is farther from the corner 76b of the display area D. Thereby, according to the manufacturing method of the display device 1 in the embodiment, the tension from the frame 72 acts on the dummy hole 88a located in the location farther from the corner 76b of the display area D more easily and deforms the hole more easily. Therefore, according to the manufacturing method of the display device 1 in the embodiment, the action of the tension from the frame 72 on the openings 86 may be suppressed. Further, the deformation of the openings 86 in the display area D is suppressed, and thereby, the reduction in accuracy of the position where the organic layer 33 is deposited in the display area D may be prevented. Accordingly, the manufacturing method that can suppress deterioration in quality of the display device 1 may be realized.

According to the manufacturing method of the display device 1 in the embodiment, the dummy hole 88a is the hole penetrating the mask foil 74, and thereby, compared to the manufacturing method of the display device 1 without the configuration, the tension from the frame 72 maybe allowed to act on the dummy hole 88a more easily. Therefore, the deformation of the openings 86 in the display area D may be suppressed, and the manufacturing method that can suppress deterioration in quality of the display device 1 may be realized.

Further, according to the manufacturing method of the display device 1 in the embodiment, the thickness of the mask foil 74 in the dummy hole 88a is smaller than the thickness of the metal foil 74 outside of the dummy hole 88a and the dummy hole 88a has the concave shape, and thereby, compared to the manufacturing method of the display device 1 without the configuration, deformation of the entire mask foil 74 may be suppressed with the tension from the frame 72 acting on the dummy hole 88a. Therefore, the deformation of the openings 86 in the display area D may be suppressed, and the manufacturing method that can suppress deterioration in quality of the display device 1 may be realized.

As above, the embodiment of the invention has been explained, however, the invention is not limited to the above described embodiment. For example, the configurations explained in the above described embodiment may be replaced by substantially the same configurations, the configurations having the same advantages, or the configurations that can achieve the same purposes.

For example, the mask 70 in the embodiment covers the plurality of organic electro luminescent display device formation areas A, however, the configuration of the mask 70 is not limited to the above described example, but may cover only a single organic electro luminescent display device formation area A.

Further, the dummy hole 88a in the embodiment is not limited to the above described configuration, but may have another configuration as long as the area of the plan view shape of the dummy hole 88a adjacent to the midpoint 72c of the side 72b of the frame 72 is larger than the area of the plan view shape of the dummy hole 88a adjacent to the corner 72a of the frame 72.

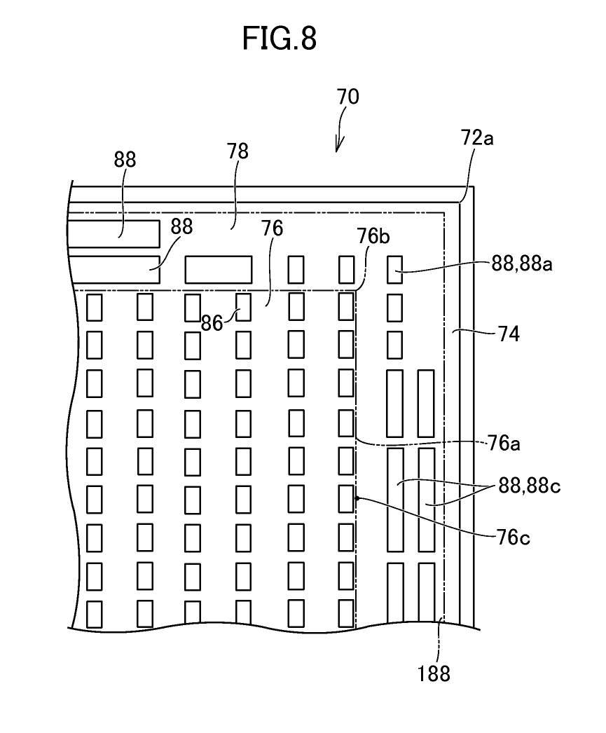

FIG. 8 is a schematic plan view showing a modified example of the mask 70 in the same visual field as that in FIG. 4. Note that, for convenience of explanation, the illustration of the area for display area 276 is omitted in FIG. 8. Specifically, for example, as shown in FIG. 8, in the plan view, a plurality of dummy holes 88a may be arranged in arbitrary locations in parallel along the outer peripheries 76a of the areas for display area 76.

According to the manufacturing method of the display device 1 in the embodiment having the configuration, compared to the manufacturing method of the display device without the configuration, the tension from the frame 72 acts more easily on the areas in which the plurality of dummy holes 88a are arranged in parallel with respect to the outer peripheries 76a. Therefore, according to the manufacturing method of the display device 1 in the embodiment, the plurality of dummy holes 88a are arranged in arbitrary locations in parallel with respect to the outer peripheries 76a, and thereby, the tension from the frame 72 may be concentrated to act on the arbitrary locations. Thus, deformation of the openings 86 may be suppressed and reduction in accuracy of the position where the organic layer 33 is deposited may be prevented.

Note that, in the example shown in FIG. 8, the dummy holes 88c adjacent to the midpoint 76c of the area for display area 76 are arranged in parallel with respect to the outer periphery 76a. In this manner, the dummy holes 88c adjacent to the midpoint 76c are arranged in parallel with respect to the outer periphery 76a, and thereby, compared to the manufacturing method of the display device without the configuration, the tension acting on the area for non-display area 78 from the frame 72 may be allowed to act on the dummy holes 88c arranged in parallel with respect to the outer periphery 76a more effectively.

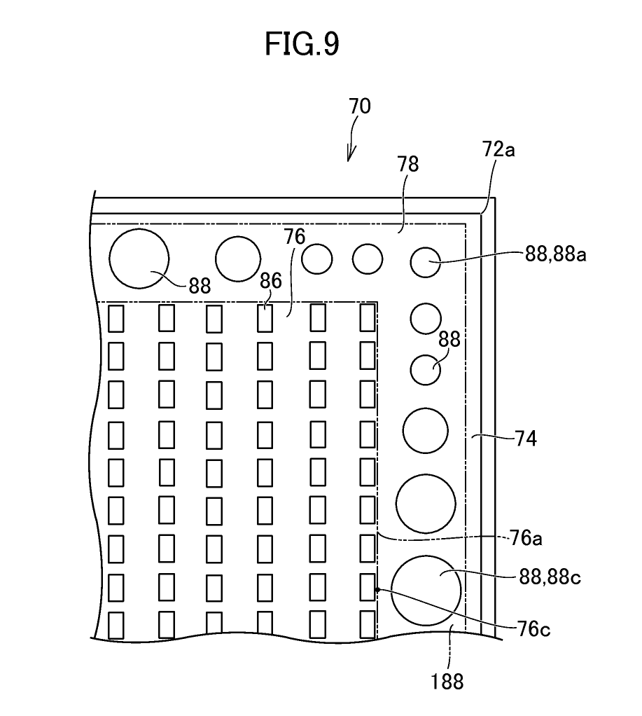

Further, the plan view shape of the dummy hole 88a in the embodiment is not limited to the rectangular shape, but may be another shape. FIG. 9 is a schematic plan view showing a modified example of the mask 70 in the same visual field as that in FIG. 4. Note that, for convenience of explanation, the illustration of the area for display area 276 is omitted in FIG. 9. Specifically, as shown in FIG. 9, the plan view shape of the dummy hole 88a may be a circular shape. “Circular shape” in the embodiment is not limited to a completely circular shape, but includes a shape deformed within the margin of error from the circular shape in the manufacturing process.

According to the manufacturing method of the display device 1 in the embodiment having the configuration, the tension from the frame 72 may homogeneously act on the dummy holes 88a. Therefore, the action of the tension from the frame 72 on the openings 86 may be suppressed. Thus, deformation of the openings 86 may be suppressed and reduction in accuracy of the position where the organic layer 33 is deposited may be prevented.

While there have been described what are at present considered to be certain embodiments of the invention, it will be understood that various modifications may be made thereto, and it is intended that the appended claim cover all such modifications as fall within the true spirit and scope of the invention.

What is claimed is:

1. A manufacturing method of a display device comprising a step of forming an organic layer having a light emitting layer in correspondence with respective pixels on a substrate having a display area having a rectangular plan view shape and a non-display area surrounding an outer periphery of the display area,
the step of forming the organic layer including a step of depositing a material of the organic layer using a mask having a frame-like frame and a mask foil fixed to the frame,
the mask foil having openings respectively corresponding to the pixels provided in an area corresponding to the display area and a plurality of dummy holes provided along an outer periphery of the area corresponding to the display area in an area corresponding to the non-display area,
wherein an area of a plan view shape of the dummy hole adjacent to a midpoint of a side of the outer periphery is larger than an area of a plan view shape of the dummy hole adjacent to a corner of the outer periphery.

2. The manufacturing method of the display device according to claim 1, wherein the plan view shape of the frame is a rectangular shape, and
an area of a plan view shape of the dummy hole adjacent to a midpoint of a side of the frame is larger than an area of a plan view shape of the dummy hole adjacent to a corner of the frame.

3. The manufacturing method of the display device according to claim 1, wherein the area of the plan view shape of the dummy hole is larger as the dummy hole is farther from the corner of the outer periphery of the area corresponding to the display area.

4. The manufacturing method of the display device according to claim 1, wherein the plan view shape of the dummy hole is a circular shape.

5. The manufacturing method of the display device according to claim 1, wherein the dummy hole penetrates the mask foil.

6. The manufacturing method of the display device according to claim 1, wherein a thickness of the mask foil in the dummy hole is smaller than a thickness of the mask foil outside of the dummy hole.
